(19) United States
(12) Patent Application Publication
(10) Pub. No.: US 2008/0278909 A1
(43) Pub. Date: Nov. 13, 2008

(54) COMPUTER ACCESSORY DEVICE HAVING RECESS FOR AIRFLOW

(76) Inventors: Jeffrey A. LEV, Cypress, TX (US); Mark S. Tracy, Tomball, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/745,375

(22) Filed: May 7, 2007

(51) Int. Cl. H05K 7/20

(52) U.S. Cl. 361/687

(57) ABSTRACT

An accessory device comprising an accessory device housing having a surface that is adapted to be adjacent a computer housing when the accessory device and computer housings are attached together. The accessory device also comprises an electrical connector provided on the surface of the accessory device housing. The electrical connector is adapted to receive an electrical mating connector from the computer housing. A recess is formed on the surface of the accessory device housing that corresponds to an air vent in the computer housing when said computer housing is attached to the accessory device, thereby enabling air to flow through the recess and air event.

### BACKGROUND

Many types of electronic device, such as computers, comprise a housing having one or more air vents for cooling purposes. Any structure that blocks the flow of air into or out of the air vent reduces the computer's cooling mechanism from functioning optimally or at all. A blocked air vent may cause the device to transition to a lower performance mode of operation to reduce the power consumption, and thus the thermal load, of the device. For example, the device may throttle its processor to a lower speed. Many electronic devices, such as notebook computers, are designed to be relatively small. This size constraint imposes significant problems in determining where to locate an air vent particularly when the device is intended to be mated with another device (e.g., a docking station).

### BRIEF DESCRIPTION OF THE DRAWINGS

For a detailed description of exemplary embodiments of the invention, reference will now be made to the accompanying drawings in which:

FIG. 1 shows an accessory device in accordance with various embodiments;

FIG. 2 shows an another accessory device in accordance with various embodiments;

FIG. 3 shows a surface of a computer comprising an air vent; and

FIGS. 4 and 5 illustrate an accessory device in conjunction with a computer.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

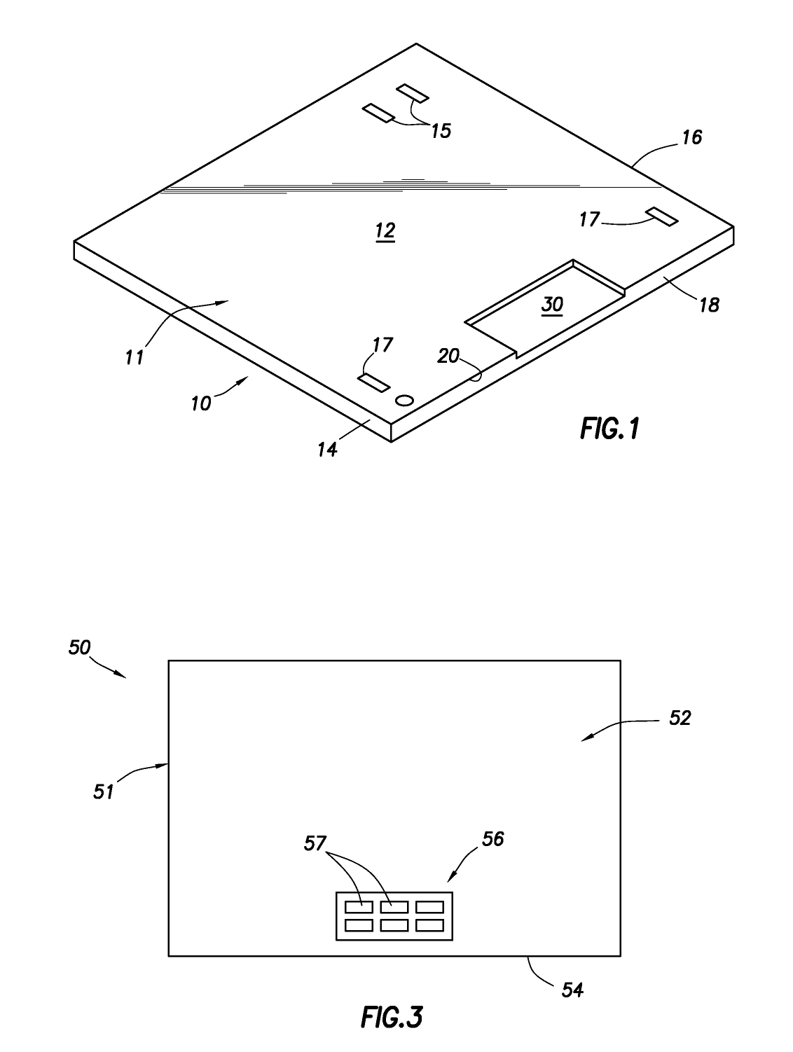

FIG. 1 shows an accessory device 10 adapted to be coupled to an electrical device such as a computer. In the embodiment of FIG. 1, the accessory device 10 comprises a battery pack that contains battery cells that provide power to the computer via an electrical connector 15. The accessory device 10 comprises an accessory device housing 11 made from plastic or other suitable material. The accessory device housing 11 comprises a surface 12 that is adapted to receive and thus be adjacent to a surface of a housing of the computer. Attachment tabs 17 insert into corresponding slots of the computer's housing to facilitate mechanical connection. When the computer is mated to the accessory device 10, electrical connectivity is established between the accessory device 10 and the computer 10 via electrical connector 15 (e.g., for charging battery cells in the accessory device 10 in the embodiment in which the accessory device comprises a battery pack).

The accessory device housing 11 is generally rectangular/square in shape, although other shapes are possible as well. In various embodiments, accessory device housing 11 comprises a size and shape that is approximately equal to the size and shape of the surface of the computer that mates with surface 12. The accessory device housing 11 comprises side surfaces 14, 16, and 18 as shown. Surface 14, 16, and 18 are generally orthogonal to surface 12. Edge 20 comprises an edge between the surface 12 and side surface 18.

A recess 30 is provided in surface 12 as shown in accordance with various embodiments. The recess 30 is formed on surface 12 along at least a portion of edge 20. The recess 30 is formed in some embodiments by removing material from surface 12. In other embodiments, the recess 30 is formed during the fabrication (e.g., injection molding) of the accessory device housing 11.

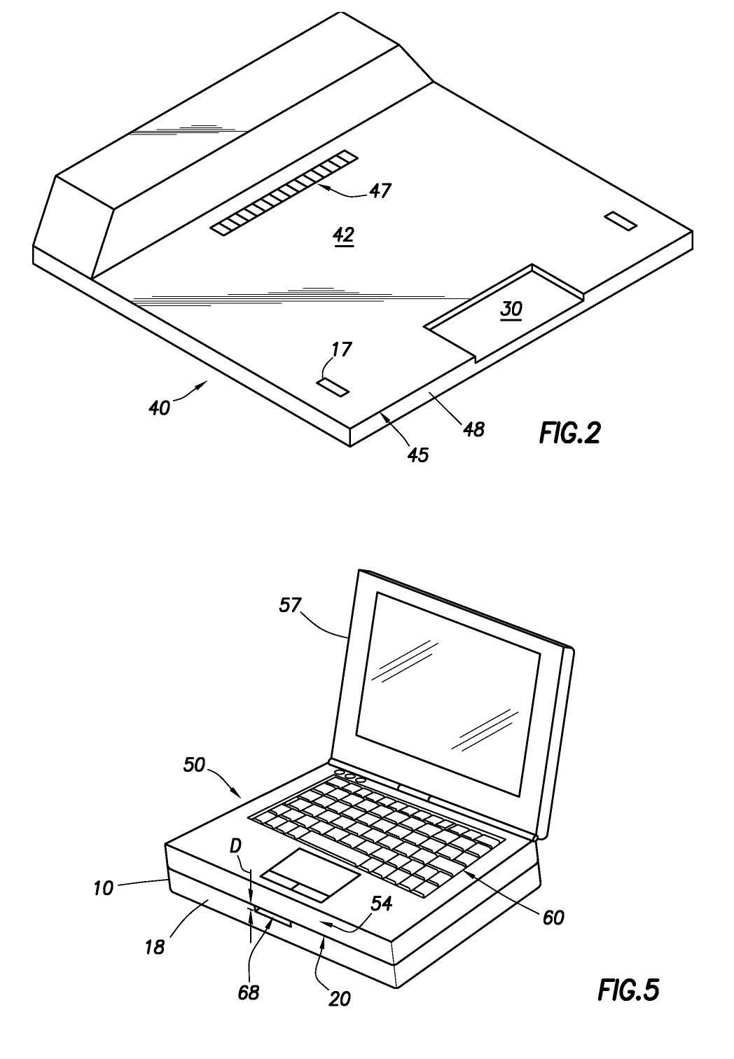

FIG. 2 shows another embodiment of an accessory device in the form of a docking station 40 to which a computer can be mated (i.e., docked). The docking station 40 comprises an electrical connector 47 which provides data and/or power connectivity between the docking station 40 and computer docked thereto. As with the accessory device 10 of FIG. 1, the docking station 40 of FIG. 2 comprises an edge 45 between orthogonal surfaces 42 and 48. The surface 42 of the docking station 40 also comprises recess 30 formed therein along edge 45.

FIG. 3 shows a bottom surface 52 of a housing 51 of a computer 50 (e.g., a notebook computer). The bottom surface 52 of the housing 51 comprises the surface that rests on a work surface (e.g., desk, table, etc.). In some embodiments, “feet” such as pads or other mechanisms may be located on the bottom surface 52 to prevent the computer or work surface from being scratched. In such embodiments, the bottom surface 52 may not directly contact the work surface.

The bottom surface 52 comprises an air vent 56 formed therein. The vent 56 comprises one or more air holes 57 through which air passes into or out of the computer 50. The air vent 56 thus facilitates airflow to help cool the heat-producing electronics of the computer 50. Any blockage of air vent 56 may have a deleterious effect on the ability of the computer 50 to be sufficiently cool.

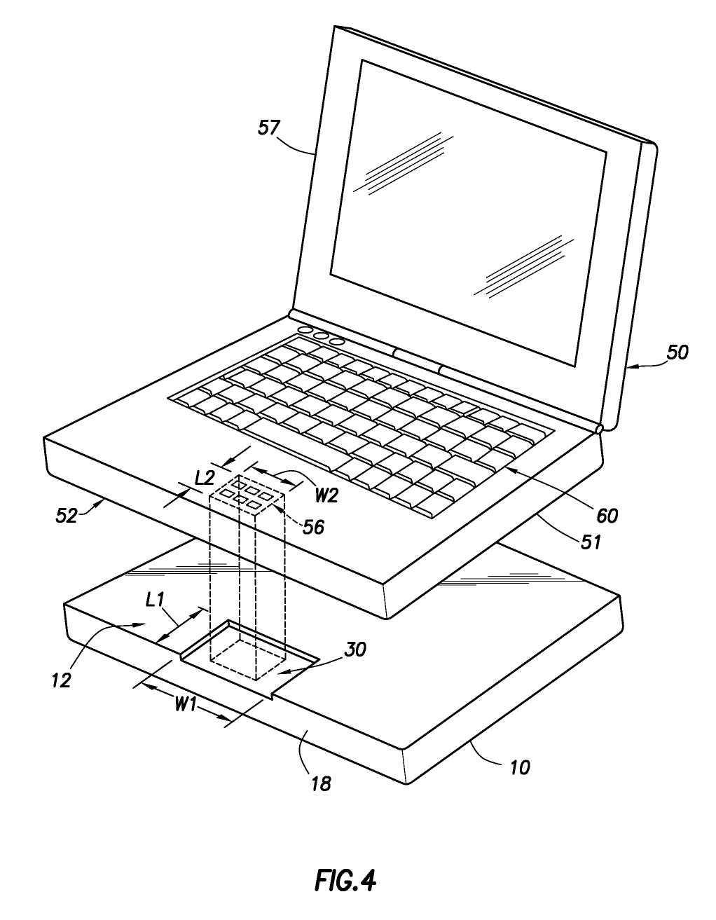

In accordance with various embodiments such as that shown in FIG. 4, the recess 30 provided on the accessory device 10 generally aligns with the air vent 56 provided on the bottom surface 52 of the computer. Thus, when the computer 50 is mated with the accessory device 10, the bottom surface 52 of the computer housing 51 generally abuts the top surface 12 of the accessory device 10. The recess 30 provides a gap, as best seen in FIG. 5 (gap 68) through which air can flow. The airflow can be forced by a fan in the computer 50 and/or accessory device 10. In other embodiments, the airflow is passive (i.e., not caused by a fan). While FIGS. 4 and 5 show the computer 50 mated to a battery pack (accessory device 10 of FIG. 1), a gap is also created when the computer 50 is mated to docking station 40 (accessory device 40 of FIG. 2).

FIGS. 4 and 5 illustrate that a keyboard 60 is provided in the housing 51 of the computer 50. A display housing 57 is also shown hinged to the housing 51.

In various embodiments, the recess 30 has an area that is larger than the area of the air vent 56, while in other embodiments the area of the recess 30 is less than the area of the air vent 56. In at least some embodiments, the recess has a depth D (FIG. 5) of from about 0.1 mm to about 5 mm. FIG. 4 illustrates that the recess 30 has a width and length of W1 and L1, respectively. The air vent 56 has a width and length of W2 and L2, respectively. In accordance with various embodiments, W1 can be the same as, or larger or smaller than, W2. Similarly, L1 can be the same as, or larger or smaller than, L2.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An accessory device, comprising:
an accessory device housing having a surface that is adapted to be adjacent a computer housing when the accessory device and computer housings are attached together;
an electrical connector provided on said surface of said accessory device housing and adapted to receive an electrical mating connector from the computer housing; and
a recess formed in said surface of said accessory device housing that corresponds to an air vent in said computer housing when said computer housing is attached to said accessory device, thereby enabling air to flow through said recess and air event.

2. The accessory device of claim 1 wherein said recess has an area that is larger than an area of said air vent.

3. The accessory device of claim 1 wherein said accessory device comprises a battery pack.

4. The accessory device of claim 1 wherein said accessory device comprises a docking station.

5. The accessory device of claim 1 wherein said recess has a depth of from 0.1 mm to 5 mm.

6. The accessory device of claim 1 wherein said recess has a width that is larger than a width of the air vent.

7. The accessory device of claim 1 wherein said recess has a length that is larger than a length of the air vent.

8. The accessory device of claim 1 wherein said accessory device housing comprises an edge between said surface and another surface orthogonal to said surface, and wherein said recess is formed along at least a portion of said edge.

9. A system, comprising:
a computer comprising a computer housing that comprises an air vent on a surface of said computer housing; and
an accessory device comprising an accessory device housing having a surface that is adapted to be adjacent said surface of said computer housing when the accessory device is mated to the computer, the accessory device housing comprises a recess in said surface of said accessory device housing and that coincides with said air vent when said accessory device is mated to said computer thereby enabling air to flow through said recess and air vent.

10. The system of claim 9 wherein said computer comprises a portable computer.

11. The system of claim 9 wherein said accessory device comprises a battery pack.

12. The system of claim 9 wherein said accessory device comprises a docking station.

13. The system of claim 9 wherein said recess has an area that is larger than an area of said air vent.

14. The system of claim 9 wherein said recess has a width that is larger than a width of the air vent.

15. The system of claim 9 wherein said recess has a length that is larger than a length of the air vent.

16. The system of claim 9 wherein said accessory device housing comprises an edge between said surface and another surface orthogonal to said surface, and wherein said recess is formed along at least a portion of said edge.

17. An apparatus, comprising:
means for receiving a surface of a computer, said computer having an air vent; and
means for providing a passageway for air to flow through said vent even when said surface of the computer is received at said means for receiving.

18. The apparatus of claim 17 wherein said means for receiving is also for providing power to said computer.

19. The apparatus of claim 17 wherein said means for receiving is also for providing data communication to said computer.
